(19) United States
(12) Patent Application Publication
(10) Pub. No.: US 2025/0287518 A1
(43) Pub. Date: Sep. 11, 2025

(54) ELECTRONIC DEVICE AND METHOD FOR MANUFACTURING ELECTRONIC DEVICE

(71) Applicant: Samsung Display Co., LTD., Yongin-si (KR)

(72) Inventors: OHJUNE KWON, Yongin-si (KR); JEONGSEOK LEE, Yongin-si (KR); JINHO HYUN, Yongin-si (KR)

(21) Appl. No.: 19/031,468

(22) Filed: Jan. 18, 2025

(30) Foreign Application Priority Data
Mar. 7, 2024 (KR) 10-2024-0032550

(51) Int. Cl. H05K 5/03; H04M 1/02

(52) U.S. Cl. CPC H05K 5/03; H04M 1/0266

(57) ABSTRACT

An electronic device includes: a display panel including a first region, and a second region adjacent to the first region; a protective layer overlapping the first region and disposed under the display panel; and an electronic module overlapping the second region and disposed below the display panel. A lower surface of the display panel includes a first lower surface overlapping the first region and a second lower surface overlapping the second region, and a contact angle between the first lower surface and water is smaller than a contact angle between the second lower surface and water.

This application claims priority to Korean Patent Application No. 10-2024-0032550, filed on Mar. 7, 2024, and all the benefits accruing therefrom under 35 U.S.C. § 119, the content of which in its entirety is herein incorporated by reference.

### BACKGROUND

The present disclosure herein relates to an electronic device and a method for manufacturing the electronic device, and more particularly, to an electronic device with improved reliability and a method for manufacturing the electronic device.

An electronic device, including a display device, such as a smartphone, a digital camera, a laptop computer, a car navigation unit, and a smart television, provides images to a user through a display screen.

The display device may include a display panel, which provides image information, and a protective layer for protecting the display panel from the outside. The protective layer protects the display panel from the outside by preventing deformation of the display panel caused by external impact and effectively dissipating heat generated from the display panel. In order to impart various functions for protecting the display panel, the protective layer adopts a stacked structure of a plurality of functional layers. Meanwhile, studies are also being conducted on an electronic device to which a single-layered protective layer in which various functions for protecting the display panel are integrated is applied, and a method for manufacturing the same.

### SUMMARY

The present disclosure provides an electronic device with improved reliability and a method for manufacturing the electronic device.

An embodiment of the invention provides an electronic device including: a display panel including a first region, and a second region adjacent to the first region; a first protective layer overlapping the first region and disposed under the display panel; and an electronic module overlapping the second region and disposed below the display panel, wherein a lower surface of the display panel includes a first lower surface overlapping the first region and a second lower surface overlapping the second region, and a contact angle between the first lower surface and water is smaller than a contact angle between the second lower surface and water.

In an embodiment, the first protective layer may include a curable resin, and a contact angle between the first lower surface and a liquid form of the curable resin may be smaller than a contact angle between the second lower surface and the liquid form of the curable resin.

In an embodiment, the first protective layer further may include a heat dissipation material dispersed in the curable resin.

In an embodiment, the electronic device may further include a heat dissipation layer disposed below the first protective layer.

In an embodiment, the first protective layer may be directly disposed on the first lower surface.

In an embodiment, in the first protective layer, a hole may be defined, and the hole may overlap the second region.

In an embodiment, the first protective layer may extend in a first direction away from the hole, and the first protective layer may include a first side surface which defines the hole and has a first inclination with respect to the lower surface of the display panel, and a second side surface which has a second inclination with respect to the lower surface of the display panel and is opposed to the first side surface in the first direction, and the first inclination being greater than the second inclination.

In an embodiment, the display panel may include: a first non-bending region including the first region and the second region; a second non-bending region facing the first non-bending region; and a bending region defined between the first non-bending region and the second non-bending region and having a predetermined radius of curvature.

In an embodiment, the electronic device may further include a circuit board disposed so as to overlap the second non-bending region.

In an embodiment, the lower surface of the display panel may further include a third lower surface overlapping the bending region, and a contact angle between the first lower surface and water may be smaller than a contact angle between the third lower surface and water.

In an embodiment, the electronic device may further include a window disposed above the display panel.

In an embodiment, the lower surface of the display panel may be formed of polyimide.

In an embodiment, the first protective layer may have a thickness of about 50 micrometers (μm) to about 300 μm.

In an embodiment of the invention, an electronic device includes: a display panel including a non-bending region, and a bending region which is adjacent to the non-bending region and has a predetermined radius of curvature; a circuit board overlapping the non-bending region and electrically connected to the display panel; and a protective layer overlapping the non-bending region and disposed under the display panel, wherein a lower surface of the display panel includes a first panel lower surface overlapping the non-bending region and a second panel lower surface overlapping the bending region, and a contact angle between the first panel lower surface and water is smaller than a contact angle between the second panel lower surface and water.

In an embodiment of the invention, a method for manufacturing an electronic device includes: providing a display panel which includes a first region and a second region adjacent to the first region, and a lower surface of which includes a first lower surface overlapping the first region and a second lower surface overlapping the second region; forming a preliminary protective layer by applying a resin composition onto the first lower surface; forming a first protective layer by curing the preliminary protective layer; and arranging an electronic module so as to overlap the second region, wherein a contact angle between the first lower surface and water is smaller than a contact angle between the second lower surface and water.

In an embodiment, in the forming of the preliminary protective layer, the applying of the resin composition may be performed through a screen printing process or a slit coating process.

In an embodiment, the forming of the preliminary protective layer may include, before the applying of the resin composition: providing a mask on the second lower surface; and providing plasma on the mask and the first lower surface.

In an embodiment, the forming of the preliminary protective layer may include, before the applying of the resin composition, providing plasma on the first lower surface, not on the second lower surface.

In an embodiment, the forming of the preliminary protective layer may include, before the applying of the resin composition, performing a hydrophobic treatment on the second lower surface.

In an embodiment, the performing of the hydrophobic treatment on the second lower surface may be performed through a water-repellent coating process.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of an electronic device according to an embodiment of the invention;

FIG. 2 is an exploded perspective view of an electronic device according to an embodiment of the invention;

FIG. 3 is a cross-sectional view of a display panel according to an embodiment;

FIGS. 4A and 4B are cross-sectional views of a partial configuration of an electronic device according to an embodiment of the invention;

FIG. 5 is a plan view of a display module according to an embodiment of the invention;

FIG. 6 is a rear view of a display module according to an embodiment of the invention;

FIGS. 7A and 7B are respectively cross-sectional views of a partial configuration of a display module according to an embodiment of the invention;

FIG. 8A is a flowchart showing a method for manufacturing an electronic device according to an embodiment of the invention;

FIG. 8B is a flowchart showing some steps of a method for manufacturing an electronic device according to an embodiment of the invention;

FIGS. 9A to 9D are cross-sectional views illustrating some steps of a method for manufacturing an electronic device according to an embodiment of the invention; and

FIGS. 10A and 10B are cross-sectional views illustrating some steps of a method for manufacturing an electronic device according to other embodiments of the invention.

### DETAILED DESCRIPTION

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

In this specification, it will be understood that “being directly disposed” means that there are no intervening layer, film, region, plate, or the like between a portion of a layer, film, region, plate, or the like and another portion thereof. For example, “being directly disposed” may mean to be disposed between two layers or two members without using an additional member such as an adhesive member or like.

Like reference numerals or symbols refer to like elements throughout. Also, in the drawings, the thicknesses, the ratios, and the dimensions of the elements are exaggerated for effective description of the technical contents. The term “and/or” includes all combinations of one or more of the associated listed elements.

Although the terms “first”, “second”, etc., may be used to describe various elements, these elements should not be limited by these terms. These terms are only used to distinguish one element from another element. For example, a first element may be referred to as a second element, and similarly, a second element may also be referred to as a first element without departing from the scope of the invention. The singular forms include the plural forms as well, unless the context clearly indicates otherwise.

Also, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the invention will be described with reference to the accompanying drawings.

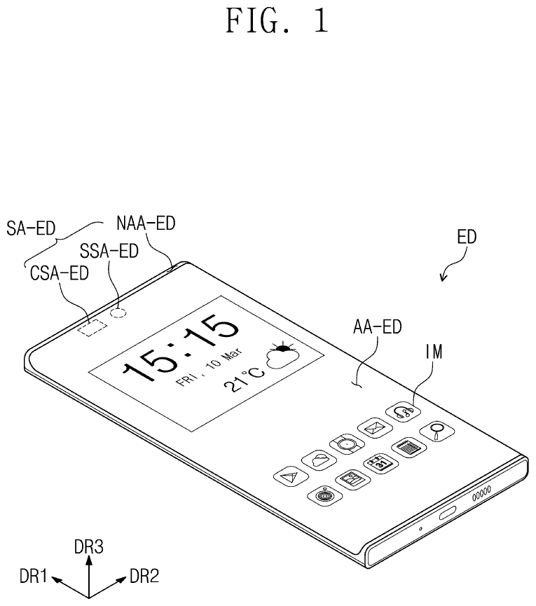

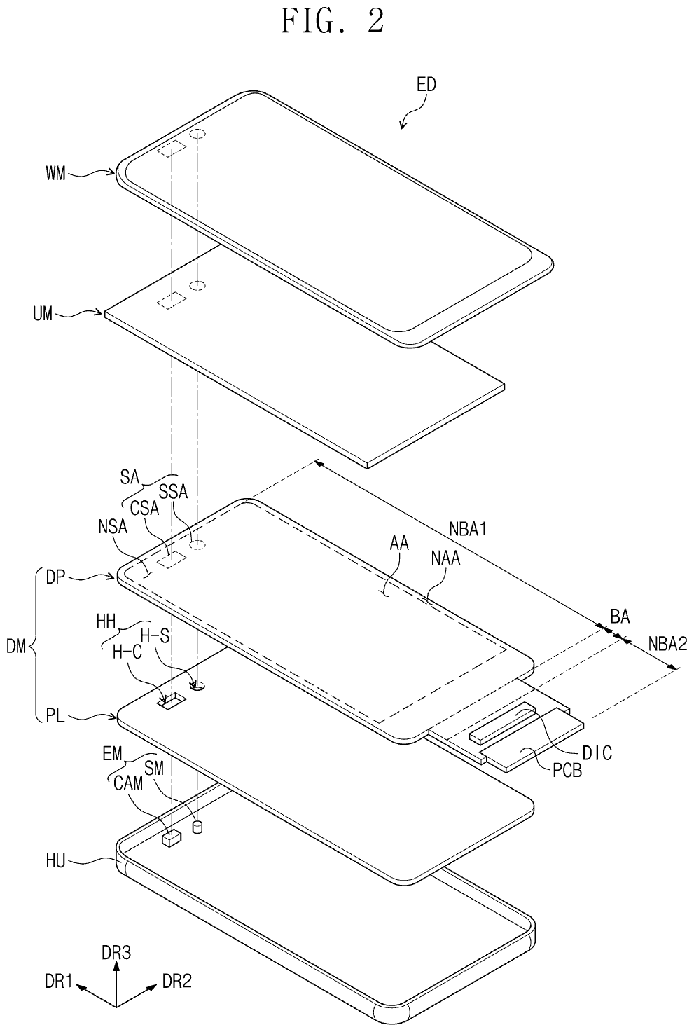

FIG. 1 is a perspective view of an electronic device ED according to an embodiment of the invention. FIG. 2 is an exploded perspective view of an electronic device ED according to an embodiment of the invention.

The electronic device ED according to an embodiment may be activated in response to an electrical signal. For example, the electronic device ED may be a mobile phone, a tablet computer, a car navigation system, a game console, or a wearable device, but an embodiment of the invention is not limited thereto. In FIG. 1, the electronic device ED is exemplarily illustrated as a mobile phone.

The electronic device ED may display an image IM through an active region AA-ED. The active region AA-ED may include a flat surface defined by a first direction DR1 and a second direction DR2. The active region AA-ED may further include a curved surface bent from at least one side of the flat surface defined by the first direction DR1 and the second direction DR2. It is illustrated that the electronic device ED, according to an embodiment, which is illustrated in FIG. 1, includes two curved surfaces which are respectively bent from both sides of the flat surface defined by the first direction DR1 and the second direction DR2. However, a shape of the active region AA-ED is not limited thereto. For example, the active region AA-ED may include only the flat surface, or further include at least two curved surfaces, for example, four curved surfaces respectively bent from four side surfaces.

Meanwhile, in FIG. 1 and the following drawings, the first direction DR1 to the third direction DR3 are illustrated, and directions respectively indicated by the first to third directions DR1, DR2, and DR3 described herein may have a relative concept and may thus be changed to other directions.

In this specification, the first direction DR1 and the second direction DR2 may be orthogonal to each other, and the third direction DR3 may be a normal direction of a plane defined by the first direction DR1 and the second direction DR2. Meanwhile, in this specification, the wording “on a plane” (i.e., in a plan view) may mean a case when viewed on a plane defined by the first direction DR1 and the second direction DR2, and a thickness direction may mean the third direction DR3 which is a normal direction of a plane defined by the first direction DR1 and the second direction DR2.

A sensing region SA-ED may be defined in the electronic device ED. FIG. 1 exemplarily illustrates a camera sensing region CSA-ED and a sensor sensing region SSA-ED, but the number of the sensing region SA-ED is not limited thereto. The sensing region SA-ED may be defined as a single region or three or more regions. Additionally, the sensing region SA-ED may be defined in the active region AA-ED to constitute a portion of the active region AA-ED.

An electronic module EM may overlap the sensing region SA-ED. The electronic module EM may receive an external input transmitted through the sensing region SA-ED, or provide an output through the sensing region SA-ED. For example, a camera module CAM may overlap the camera sensing region CSA-ED, and a sensor module SM may overlap the sensor sensing region SSA-ED.

The electronic device ED may include the active region AA-ED and a peripheral region NAA-ED adjacent to the active region AA-ED. The active region AA-ED may be a portion corresponding to an active region AA of a later-described display panel DP, and the peripheral region NAA-ED may be a portion corresponding to a peripheral region NAA of the display panel DP.

The peripheral region NAA-ED, which is a region for blocking a light signal, may be disposed outside the active region AA-ED and surround the active region AA-ED. In an embodiment, the peripheral region NAA-ED may be disposed not on a front surface but on a side surface of the electronic device ED. The peripheral region NAA-ED according to an embodiment may be omitted.

The electronic device ED of an embodiment includes a window WM, an upper member UM, a display module DM, a housing HU, and the electronic module EM.

The electronic device ED according to an embodiment may include the window WM disposed on a display panel DP. The window WM provides an exterior surface of the electronic device ED. The window WM may cover a front surface of the display panel DP and protect the display panel DP against external impacts and scratches. The window WM may be coupled to the upper member UM via an adhesive layer.

The window WM may include an optically transparent insulating material. For example, the window WM may include a glass film or a synthetic resin film as a base film. The window WM may have a single- or multi-layered structure. For example, the window WM may include a plurality of plastic films bonded with an adhesive, or may include a glass film and a plastic film bonded with an adhesive. The window WM may further include functional layers such as an anti-fingerprint layer, a phase control layer, and a hard coating layer, which are disposed on the transparent film.

In the electronic device ED according to an embodiment, the upper member UM may be disposed below the window WM and above the display module DM. The upper member UM may include an anti-reflection layer and an input detection sensor. The anti-reflection layer reduces an external light reflectance. The input detection sensor detects an external input from a user. The upper member UM may further include an adhesive layer which bonds the anti-reflection layer and the Input detection sensor.

In the electronic device ED according to an embodiment, the display module DM may be disposed below the upper member UM. The display module DM may include the display panel DP and a protective layer PL disposed under the display panel DP.

The display panel DP may include the active region AA in which the image IM is displayed and the peripheral region NAA adjacent to the active region AA. That is, a front surface of the display panel DP may include the active region AA and the peripheral region NAA. The active region AA may be a region which is activated in response to an electrical signal and generates the image IM displayed in the active region AA-ED of the electronic device ED.

The peripheral region NAA may be adjacent to the active region AA. The peripheral region NAA may surround the active region AA. A driving circuit or a driving wire for driving the active region AA, various types of signal lines or pads for providing electrical signals to the active region AA, or the like, may be disposed in the peripheral region NAA.

The display panel DP may include a first non-bending region NBA1, a second non-bending region NBA2, and a bending region BA defined between the first non-bending region NBA1 and the second non-bending region NBA2. The bending region BA may be defined as a portion which is bent with respect to a predetermined axis extending in the first direction DR1. As the display panel DP in the bending region BA is bent, the display panel DP in the second non-bending region NBA2 may be disposed below the display panel DP in the first non-bending region NBA1.

The first non-bending region NBA1 of the display panel DP may include the active region AA in which pixels are included. A region, other than the active region AA, of the first non-bending region NBA1, the bending region BA, and the second non-bending region NBA2 may correspond to the peripheral region NAA.

A driving element DIC for driving the display panel DP may be mounted on the second non-bending region NBA2 of the display panel DP. A display pad (not illustrated) disposed adjacent to an end of the second non-bending region NBA2 may be included in the second non-bending region NBA2 of the display panel DP. A circuit board PCB may be disposed on an end portion of the second non-bending region NBA2 of the display panel DP. However, an embodiment of the invention is not limited thereto, and the driving element DIC may be mounted on the circuit board PCB.

The circuit board PCB may overlap the second non-bending region NBA2. The circuit board PCB may transmit signals for controlling the image IM (see FIG. 1) or power supply signals from a main board within the electronic device ED to the display panel DP. The circuit board PCB may be a flexible circuit board. The circuit board PCB may include a circuit pad (not illustrated) disposed adjacent to an end thereof. The circuit pad (not illustrated) may be connected to the display pad (not illustrated). Accordingly, the display panel DP and the circuit board PCB may be electrically connected to each other.

The display panel DP may include a first region NSA and a second region SA adjacent to the first region NSA. The second region SA may be a region overlapping the electronic module EM, and the first region NSA may be a region surrounding at least a portion of the second region SA. For example, as illustrated in FIG. 2, the first region NSA may be a region surrounding the entire circumference of the second region SA. The second region SA may correspond to the sensing region SA-ED of the electronic device ED. The first region NSA may correspond to a whole region of the first non-bending region NBA1, except for the second region SA.

The second region SA may include a first signal transmission region CSA corresponding to the camera sensing region CSA-ED of the electronic device ED, and a second signal transmission region SSA corresponding to the sensor sensing region SSA-ED of the electronic device ED. Below the display panel DP, a camera module CAM may be disposed so as to overlap the first signal transmission region CSA, and a sensor module SM may be disposed so as to overlap the second signal transmission region SSA. Although not illustrated, a predetermined opening may be defined in a portion of the second regions SA of the display panel DP. That is, a portion of the display panel DP corresponding to one region of the second regions SA may be penetrated.

FIG. 2 exemplarily illustrates that the second region SA includes the first signal transmission region CSA and the second signal transmission region SSA, that is, two transmission regions. However, the number of the second region SA is not limited thereto. For example, the second region SA of the display panel DP may be defined as a single region, or three or more regions. Also, FIG. 2 exemplarily illustrates that the second region SA has a circular shape or a quadrilateral shape. However, a shape of the second region SA is not limited thereto, and may be variously defined.

On a plane, the area of the second region SA may be smaller than the area of the first region NSA. The light transmittance of the first region NSA may differ from a light transmittance of the second region SA. The light transmittance of the second region SA may be greater than the light transmittance of the first region NSA.

Meanwhile, in the display panel DP according to an embodiment, a portion of a driving circuit, a driving wire, or the like for driving pixels disposed in the second region SA may be disposed in a portion of the first region NSA adjacent to the second region SA, or the peripheral region NAA. Accordingly, the wiring density in the second region SA may be smaller than the wiring density in the first region NSA. However, an embodiment of the invention is not limited thereto, and the wiring density in the second region SA may be substantially the same as the wiring density in the first region NSA.

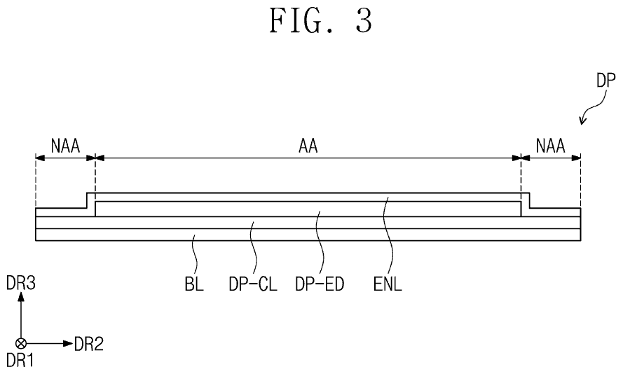

The display panel DP may include a light-emitting element layer DP-ED (see FIG. 3) including an organic light-emitting element, a quantum dot light-emitting element, a micro-LED light-emitting element, or a nano-LED light-emitting element, and the like. The light-emitting element layer DP-ED (see FIG. 3) may be configured to substantially generate images.

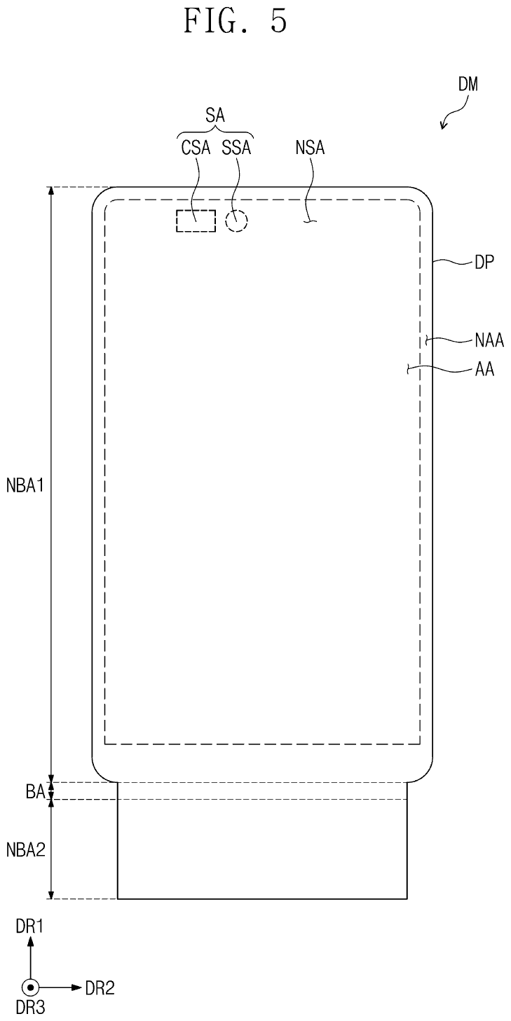

The protective layer PL may be disposed under the display panel DP. The protective layer PL may be a member which supports the display panel DP, absorbs an impact applied to the display panel DP, and performs a heat dissipation function of dissipating heat generated in components, such as an electronic module EM, disposed below the display panel DP. The details of the protective layer PL will be described later with reference to FIG. 5.

A hole HH may be defined in the protective layer PL. The hole HH may be defined in a region corresponding to the electronic module EM. The hole HH may be defined so as to overlap the second region SA of the display panel DP. In an embodiment, the hole HH of the coating layer PL may be defined as a single hole or a plurality of holes. The hole HH may include a sensor hole H-S and a camera hole H-C.

FIG. 2 illustrates that the hole HH is defined only in the protective layer PL. However, an embodiment of the invention is not limited thereto, and a predetermined opening may be additionally defined in the display panel DP. The hole HH may overlap the electronic module EM. At least a portion of the electronic module EM may be disposed to be inserted into the hole HH.

In the electronic device ED according to an embodiment, the electronic module EM may be an electronic component which outputs or receives a light signal. For example, the electronic module EM may include the camera module CAM and the sensor module SM. The camera module CAM may receive external light through the camera sensing region CSA-ED and capture an external image. Also, the sensor module SM may be a sensor such as a proximity sensor or infrared light-emitting sensor which outputs or receives external light through the sensor sensing region SSA-ED.

In addition to the above-described electronic module EM, the electronic device ED according to an embodiment may further include a power supply module, a control module, a wireless communication module, an image input module, a sound input module, a sound output module, a memory, an external interface module, and the like. The electronic device ED may include a main circuit board, and the modules may be mounted on the main circuit board or be electrically connected to the main circuit board via a flexible circuit board. The power supply module may supply power required for an overall operation of the electronic device ED. For example, the power supply module may include a typical battery device.

FIG. 3 is a cross-sectional view of a display panel according to an embodiment of the invention.

Referring to FIG. 3, a display panel DP according to an embodiment may include a base layer BL, a circuit layer DP-CL disposed on the base layer BL, a light-emitting element layer DP-ED, and an encapsulation layer ENL.

The base layer BL may include a plastic substrate, a glass substrate, a metal substrate, an organic/inorganic composite material substrate, or the like. For example, the base layer BL may include at least one polyimide layer. The protective layer PL described above may be disposed under the base layer BL.

The circuit layer DP-CL includes at least one insulating layer, semiconductor patterns, and conductive patterns. The insulating layer includes at least one inorganic layer and at least one organic layer. The semiconductor patterns and the conductive patterns may form signal lines, a pixel driving circuit, and a scan driving circuit. Additionally, the circuit layer DP-CL may include a rear surface metal layer.

The light-emitting element layer DP-ED includes a display element, for example, a light-emitting element. For example, the light-emitting element may be an organic light-emitting element, a quantum dot light-emitting element, a micro-LED light-emitting element, or a nano-LED light-emitting element. The light-emitting element layer DP-ED may further include an organic layer such as a pixel-defining film.

The light-emitting element layer DP-ED may be disposed in an active region AA. A peripheral region NAA is disposed in outer peripheries of the active region AA and surrounds the active region AA. A light-emitting element may not be disposed in the peripheral region NAA.

The encapsulation layer ENL may be disposed on the light-emitting element layer DP-ED and cover the light-emitting element layer DP-ED. The encapsulation layer ENL may be disposed on the circuit layer DP-CL so as to seal the light-emitting element layer DP-ED. The encapsulation layer ENL may be a thin-film encapsulation layer including a plurality of organic thin films and inorganic thin films. The encapsulation layer ENL may include a thin-film encapsulation layer having a stacked structure of an inorganic layer/an organic layer/an inorganic layer. A stacked structure of the encapsulation layer ENL is not particularly limited.

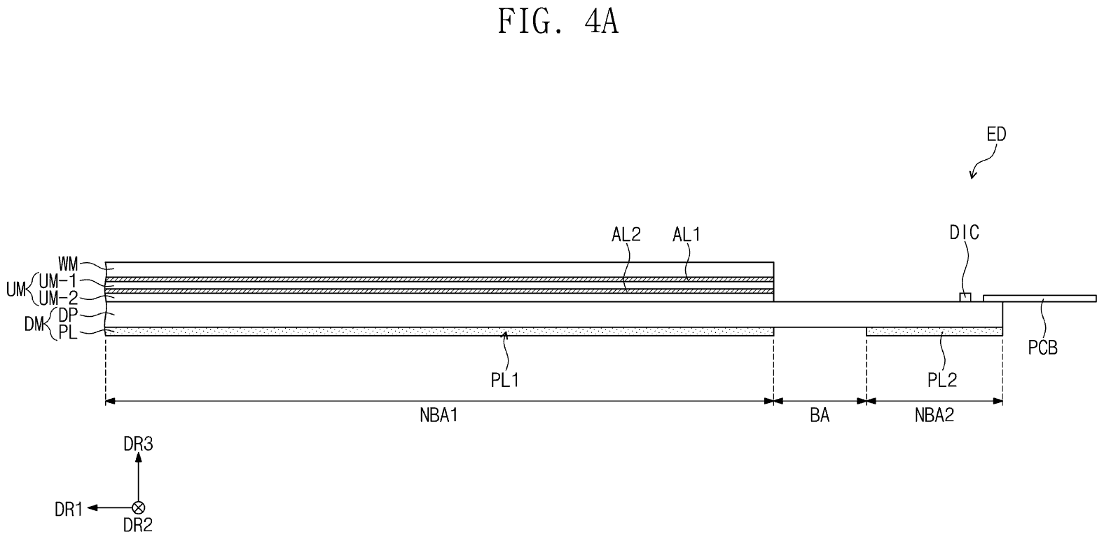

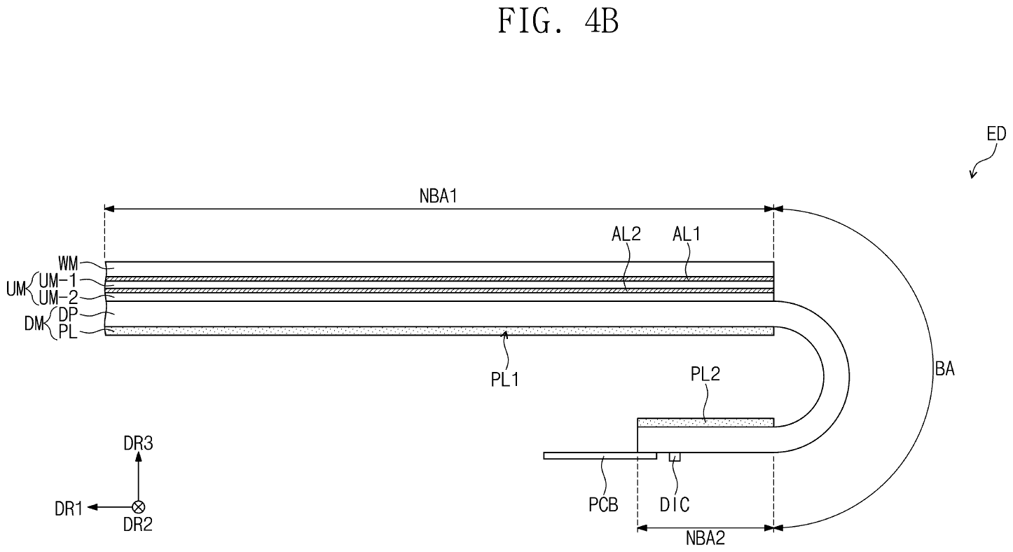

FIGS. 4A and 4B are respectively cross-sectional views of a partial configuration of an electronic device according to an embodiment of the invention. FIG. 4A illustrates a state in which a display panel DP is not bent, and FIG. 4B illustrates a state in which a bending region BA of the display panel DP is bent in an electronic device ED according to an embodiment of the invention. Hereinafter, the same/similar reference numerals or symbols are used for the components same/similar to those described in FIGS. 1 to 3, and a duplicated description thereof will be omitted.

Referring to FIGS. 4A and 4B, the electronic device ED according to an embodiment of the invention may include a window WM, an upper member UM, and a display module DM.

In an embodiment, the electronic device ED may include a front surface and a rear surface. The front surface of the electronic device ED may be defined in the window WM, and the rear surface of the electronic device ED may be defined in a protective layer PL.

The window WM may cover a front surface of the display panel DP. The window WM may include a base substrate (not illustrated) and a bezel pattern (not illustrated). The base substrate (not illustrated) includes a transparent base layer, such as a glass substrate or a transparent film. The bezel pattern may have a multi-layered structure. The multi-layered structure may include a colored color layer and a black light blocking layer.

The upper member UM includes an anti-reflection layer UM-1 and an input sensor UM-2. The window WM and the anti-reflection layer UM-1 may be bonded via a first adhesive layer AL1, and the anti-reflection layer UM-1 and the input sensor UM-2 may be bonded via a second adhesive layer AL2. Meanwhile, at least one of the first adhesive layer AL1 or the second adhesive layer AL2 may be omitted. For example, the second adhesive layer AL2 may be omitted, and the anti-reflection layer UM-1 may be directly disposed on the input sensor UM-2.

The anti-reflection layer UM-1 may reduce an external light reflectance. The anti-reflection layer UM-1 may include a retarder and/or a polarizer. The anti-reflection layer UM-1 may include a polarizing film or color filters. The color filters may have a predetermined arrangement. The arrangement of the color filters may be determined in consideration of colors of light emitted from pixels included in the display panel DP. The anti-reflection layer UM-1 may include a division layer adjacent to the color filters.

The input sensor UM-2 may include a plurality of sensing electrodes (not illustrated) for detecting an external input, trace lines (not illustrated) connected to the plurality of sensing electrodes, and an inorganic layer and/or an organic layer for insulating/protecting the plurality of sensing electrodes or trace lines. The input sensor UM-2 may be a capacitive sensor, but is not particularly limited thereto.

The input sensor UM-2 may be directly formed on a thin-film encapsulation layer through a continuous process during the manufacturing of the display panel DP. However, an embodiment of the invention is not limited thereto. The input sensor UM-2 may be manufactured as a panel separately from the display panel DP and then attached to the display panel DP via an adhesive layer.

The display module DM may include the display panel DP and the protective layer PL disposed under the display panel DP.

The protective layer PL may be directly disposed below the display panel DP. The protective layer PL may be in contact with a lower surface of the display panel DP. An additional adhesive member may not be disposed between the protective layer PL and the display panel DP. The protective layer PL may have a thickness of about 50 μm to about 300 μm. For example, the protective layer PL may have a thickness of about 100 μm to about 200 μm.

In the display module DM of an embodiment, the single-layered protective layer PL may be provided on the lower surface of the display panel DP. The protective layer PL may be a member which supports the display panel DP, absorbs an impact applied to the display panel DP, and performs a heat dissipation function of dissipating heat generated in components disposed below the display panel DP such as an electronic module EM. Since in the electronic device ED according to an embodiment, the single-layered protective layer PL performs not only an impact absorbing function but also a heat dissipation function, etc., a thickness of the electronic device ED may be reduced, and components may be simplified, thereby making it possible to increase process efficiency during the manufacturing of the electronic device ED according to an embodiment. However, an embodiment of the invention is not limited thereto. Although not illustrated, the electronic device ED of an embodiment may further include at least one among an impact absorbing layer, a heat dissipation layer, a shielding layer, and a support layer, which are disposed below the protective layer PL.

The protective layer PL may include a base resin. The protective layer PL may include a base resin having curability. For example, the protective layer PL may include a thermosetting resin or a photocurable resin. The protective layer PL may include at least one among an acylate-based resin, a urethane-based resin, a fluorine-based resin, an epoxy-based resin, a polyester-based resin, a polyamide-based resin, and a silicone-based resin, which have curability. The protective layer PL may further include a plurality of fillers dispersed in a base resin. The plurality of fillers may perform a shielding function, a heat dissipation function, or an impact absorbing function.

The protective layer PL may include a first protective layer PL1 overlapping a first non-bending region NBA1, and a second protective layer PL2 overlapping a second non-bending region NBA2. On a plane defined by the first direction DR1 and the second direction DR2, the first protective layer PL1 and the second protective layer PL2 may not overlap with the bending region BA therebetween. The details of the first protective layer PL1 and the second protective layer PL2 will be described later with reference to FIG. 5.

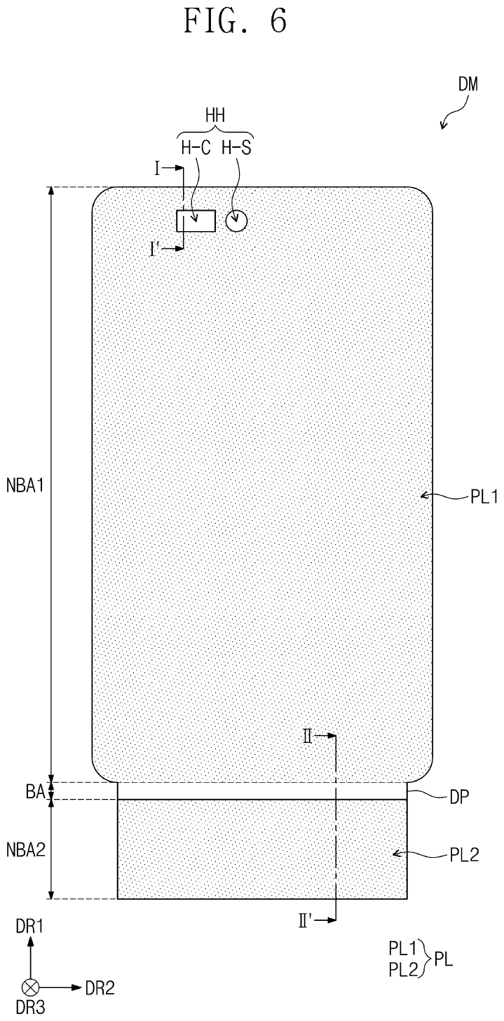

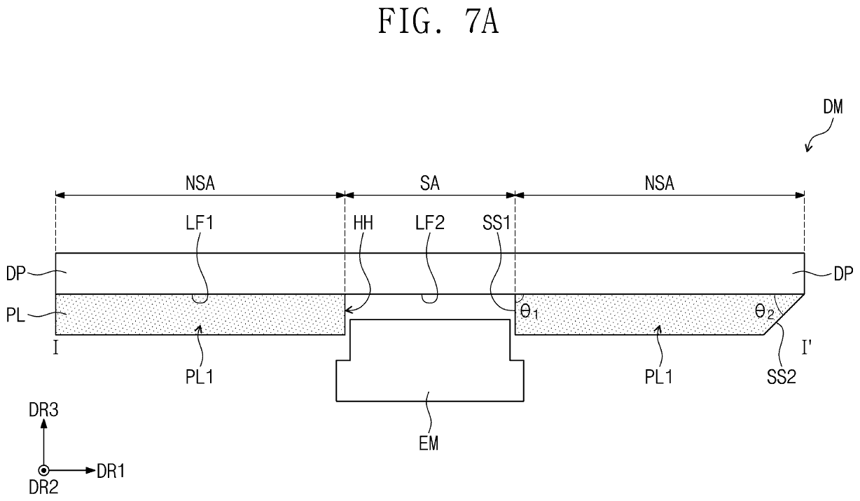

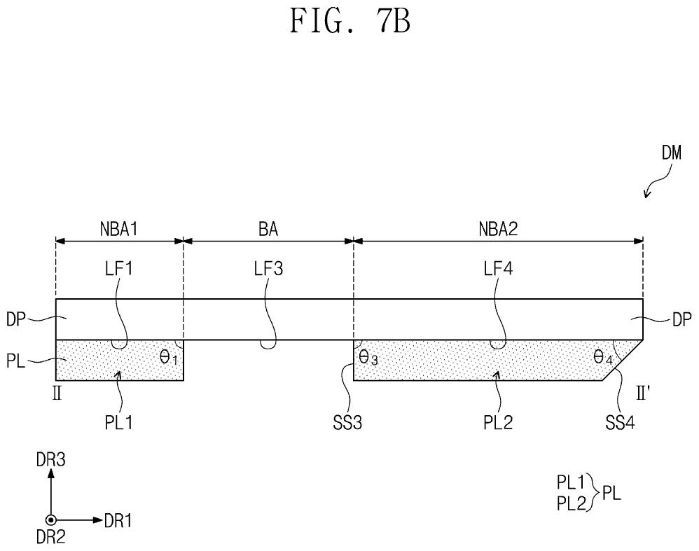

FIG. 5 is a plan view of a display module according to an embodiment of the invention. FIG. 6 is a rear view of a display module according to an embodiment of the invention. FIGS. 7A and 7B are respectively cross-sectional views of a partial configuration of a display module according to an embodiment of the invention. FIG. 7A illustrates a cross-section taken along line I-I′ illustrated in FIG. 6, and FIG. 7B illustrates a cross-section taken along line II-II′ illustrated in FIG. 6.

Referring to FIGS. 5 and 6, a display module DM may include a display panel DP and a protective layer PL disposed under the display panel DP. The display module DM may be composed of the display panel DP and the protective layer PL.

The protective layer PL may be directly disposed below the display panel DP. The lower surface, of the display panel DP on which the protective layer PL is disposed, may have lower hydrophobicity than the lower surface of the display panel DP on which the protective layer PL is not disposed. That is, the display panel DP in the second region SA and the bending region BA on which the protective layer PL is not disposed may have relatively higher hydrophobicity than the other region.

The protective layer PL may include a first protective layer PL1 overlapping a first non-bending region NBA1, and a second protective layer PL2 overlapping a second non-bending region NBA2. The first protective layer PL1 and the second protective layer PL2 may be members formed of substantially the same material except that overlapping regions thereof differ from each other. For example, the first protective layer PL1 and the second protective layer PL2 may be formed of the same material and through the same process at the same time. The thickness of the first protective layer PL1 may be substantially the same as the thickness of the second protective layer PL2. Meanwhile, in this specification, the wording “substantially the same” includes not only a case where components have physically completely the same thickness, etc., but also a case where in spite of being identically designed, components have a difference in thicknesses, etc., by tolerances which occur during a process.

Referring to FIGS. 5, 6 and 7A, the first non-bending region NBA1 may be divided into a first region NSA and a second region SA, and the first protective layer PL1 overlaps the first region NSA. The lower surface of the display panel DP may include a first lower surface LF1 overlapping the first region NSA, and the first protective layer PL1 may be in contact with the first lower surface LF1. The first protective layer PL1 may not overlap the second region SA. The lower surface of the display panel DP may include a second lower surface LF2 overlapping the second region SA, and the first protective layer PL1 may not be in contact with the second lower surface LF2. The display panel DP may include the base layer BL (see FIG. 3), and the first and second lower surfaces LF1 and LF2 of the display panel DP may be formed of the polyimide (PI) included in the base layer BL (see FIG. 3).

In the display panel DP, the hydrophobicity of the first lower surface LF1 is lower than the hydrophobicity of the second lower surface LF2. The contact angle between the first lower surface LF1 and water is smaller than the contact angle between the second lower surface LF2 and water. As used herein, the contact angle means an angle between a surface of a solid object (e.g., the first lower surface of the display panel) and a surface tangent on liquid (e.g., water, resin in liquid form) at their intersection when the water is disposed on the surface of the solid object. In an embodiment, the first protective layer PL1 may include the above-described curable resin, and the contact angle between the first lower surface LF1 and a liquid form of the curable resin included in the first protective layer PL1 may be smaller than the contact angle between the second lower surface LF2 and the liquid form of the curable resin. When manufacturing the electronic device ED (see FIG. 1) according to an embodiment of the invention, a step of performing a hydrophilic treatment on the first lower surface LF1 is performed, or a step of performing a hydrophobic treatment on the second lower surface LF2 is performed, and thus the first lower surface LF1 may differ in characteristics from the second lower surface LF2.

A hole HH overlapping the second region SA may be defined in the first protective layer PL1. The first protective layer PL1 may be disposed to surround the hole HH. The hole HH may be defined in a region corresponding to an electronic module EM. The hole HH may be defined so as to overlap the second region SA of the display panel DP. In an embodiment, the hole HH of the first protective layer PL1 may be defined as single hole or a plurality of holes. The first protective layer PL1 may include a sensor hole H-S and a camera hole H-C.

The first protective layer PL1 may include a first side surface SS1 and a second side surface SS2. The first side surface SS1 may define the hole HH among side surfaces of the first protective layer PL1. On a plane defined by the first direction DR1 and the second direction DR2, the first protective layer PL1 may extend in one direction away from the hole HH, and the second side surface SS2 may be defined as a surface opposed to the first side surface SS1 with respect to the one direction. FIG. 7A illustrates that the first protective layer PL1 extends in the first direction DR1 away from the hole HH and the first side surface SS1 and the second side surface SS2 are opposed to each other with respect to the first direction DR1.

The first side surface SS1 may have a first inclination θ₁ with respect to the first lower surface LF1 of the display panel DP, and the second side surface SS2 may have a second inclination θ₂ with respect to the first lower surface LF1 of the display panel DP. The first inclination θ₁ may have a value greater than a value of the second inclination θ₂. For example, the first inclination θ₁ may be about 90 degrees, and the second inclination θ₂ may have a value of about 80 degrees or more and less than 90 degrees, but an embodiment of the invention is not limited thereto. Also, for convenience of description, FIG. 7A illustrates the first side surface SS1, and the second side surface SS2 opposed to the first side surface SS1, but the first side surface SS1 defining the hole HH has a relatively greater inclination with respect to the lower surface of the display panel DP than other side surfaces, of the protective layer PL, not adjacent to the hole HH. For example, the first side surface SS1 may have a relatively greater inclination with respect to the lower surface of the display panel DP than four side surfaces, of the protective layer PL, adjacent to four side surfaces of the electronic device ED (see FIG. 1). When manufacturing the electronic device ED (see FIG. 1) according to an embodiment of the invention, a step of performing a hydrophilic treatment on the first lower surface LF1 is performed, or a step of performing a hydrophobic treatment on the second lower surface LF2 is performed, and thus the first side surface SS1 defining the hole HH may be orthogonal to the lower surface of the display panel DP. Therefore, the planarity of the first protective layer PL1 adjacent to the hole HH is increased, thereby making it possible to improve the reliability of the electronic device ED (see FIG. 1) including the first protective layer PL1.

Referring to FIGS. 5, 6 and 7B, the second protective layer PL2 may overlap the second non-bending region NBA2. The first protective layer PL1 and the second protective layer PL2 may not overlap the bending region BA. The lower surface of the display panel DP may include a third lower surface LF3 overlapping the bending region BA, and a fourth lower surface LF4 overlapping the second non-bending region NBA2. The second protective layer PL2 may be in contact with the fourth lower surface LF4 and may not be in contact with the third lower surface LF3. Meanwhile, in this specification, the second non-bending region NBA2 may be referred to as “a non-bending region”, the third lower surface LF3 may be referred to as “a second panel lower surface”, and the fourth lower surface LF4 may be referred to as “a first panel lower surface”.

In the display panel DP, the hydrophobicity of the first lower surface LF1 may be lower than the hydrophobicity of the third lower surface LF3. The contact angle between the first lower surface LF1 and water may be smaller than the contact angle between the third lower surface LF3 and water. Also, the hydrophobicity of the fourth lower surface LF4 may be lower than hydrophobicity of the third lower surface LF3, and the contact angle between the fourth lower surface LF4 and water may be smaller than the contact angle between the third lower surface LF3 and water. When manufacturing the electronic device ED (see FIG. 1) according to an embodiment of the invention, a step of performing a hydrophilic treatment on the fourth lower surface LF4 is performed, or a step of performing a hydrophobic treatment on the third lower surface LF3 is performed, and thus the third lower surface LF3 may differ in characteristics from the fourth lower surface LF4.

The second protective layer PL2 may include a third side surface SS3 and a fourth side surface SS4. The third side surface SS3 may be defined as one surface adjacent to the bending region BA among side surfaces of the second protective layer PL2. On a plane defined by the first direction DR1 and the second direction DR2, the second protective layer PL2 may extend in one direction away from the bending region BA, and the fourth side surface SS4 may be defined as a surface opposed to the third side surface SS3 with respect to the one direction. FIG. 7B illustrates that the second protective layer PL2 extends in the first direction DR1 away from the bending region BA and the third side surface SS3 and the fourth side surface SS4 are opposed to each other with respect to the first direction DR1.

The third side surface SS3 may have a third inclination θ₃ with respect to the third lower surface LF3 of the display panel DP, and the fourth side surface SS4 may have a fourth inclination θ₄ with respect to the fourth lower surface LF4 of the display panel DP. The third inclination θ₃ may have a value greater than a value of the fourth inclination θ₄. When manufacturing the electronic device ED (see FIG. 1) according to an embodiment of the invention, a step of performing a hydrophobic treatment on the third lower surface LF3 is performed, or a step of performing a hydrophilic treatment on the fourth lower surface LF4 is performed, and thus the third side surface SS3 adjacent to the bending region BA may be orthogonal to the lower surface of the display panel DP.

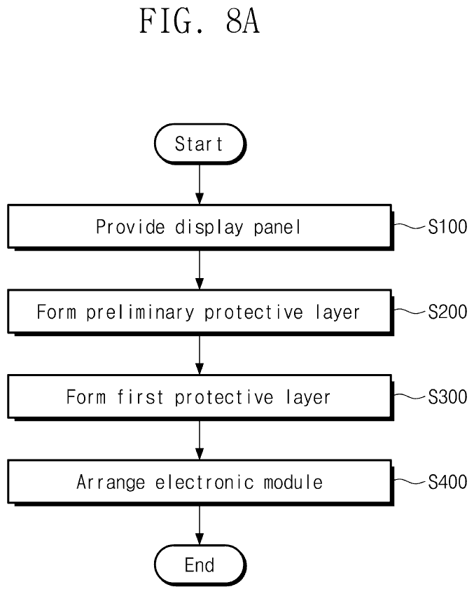

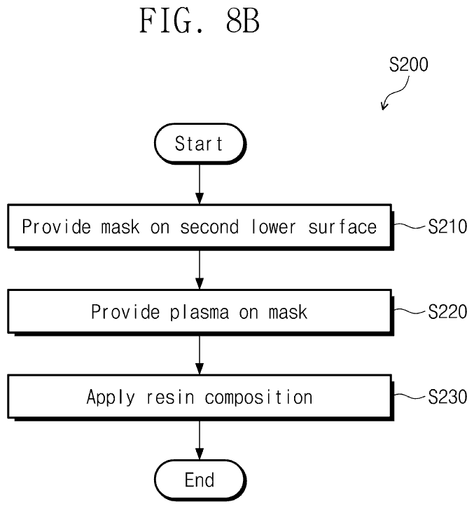

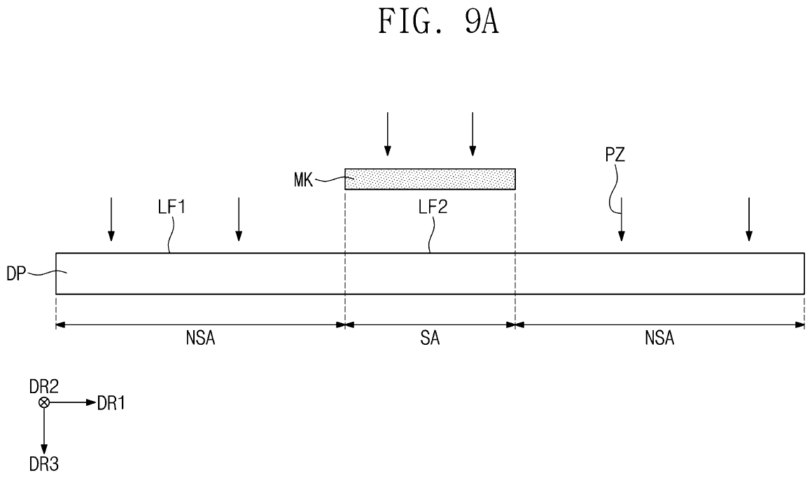

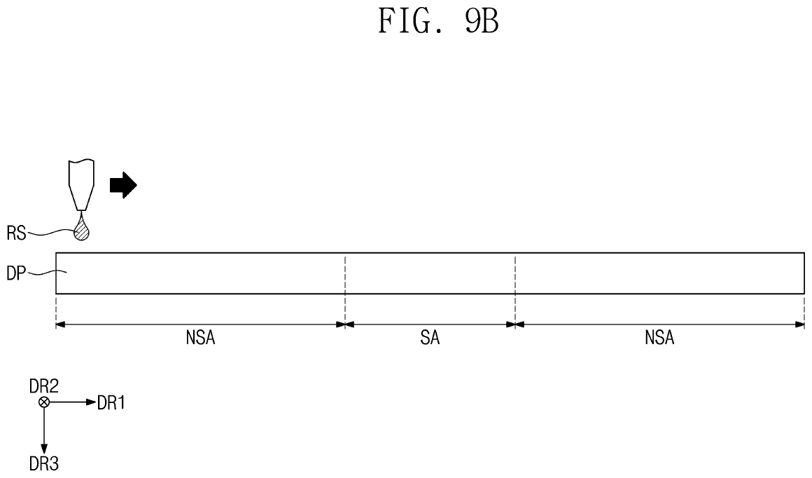

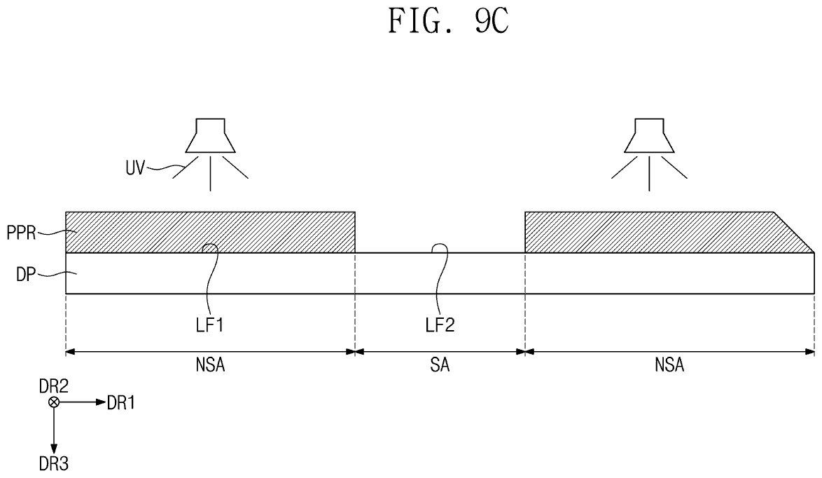

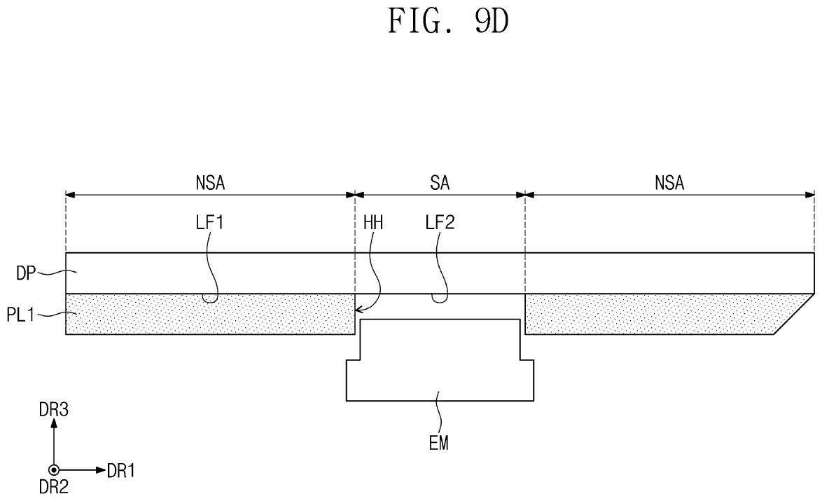

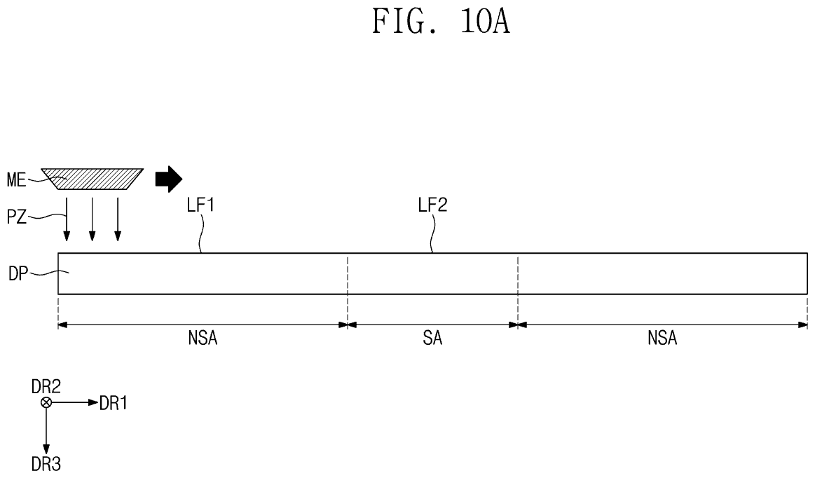

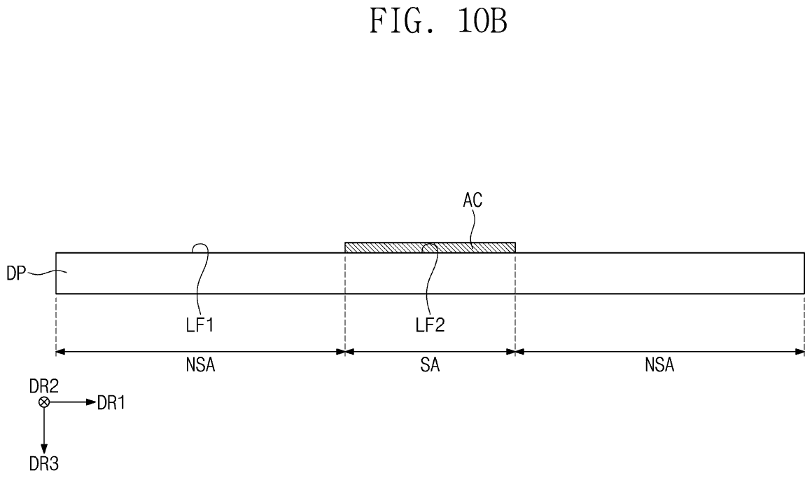

FIG. 8A is a flowchart showing a method for manufacturing an electronic device according to an embodiment. FIG. 8B is a flowchart showing some steps of the method for manufacturing the electronic device according to an embodiment. FIGS. 9A to 9D are cross-sectional views illustrating some steps of a method for manufacturing an electronic device according to an embodiment of the invention. FIGS. 10A and 10B are cross-sectional views illustrating some steps of a method for manufacturing an electronic device according to other embodiments of the invention. The method for manufacturing the electronic device of an embodiment may illustrate the method for manufacturing the electronic device ED of an embodiment illustrated in FIGS. 1 to 7B. In an embodiment, the method for manufacturing the electronic device including a first protective layer PL1 disposed under a display panel DP is provided. Hereinafter, referring to FIGS. 8A, 8B, 9A to 9D, 10A and 10B, in the description of the method for manufacturing the electronic device of an embodiment, the same reference numerals or symbols are used for the components duplicated with those described above, and a detailed description thereof will be omitted.

Referring to FIG. 8A, the method for manufacturing the electronic device according to an embodiment includes steps of: providing a display panel (S100), forming a preliminary protective layer (S200), forming a first protective layer (S300), and arranging an electronic module (S400). Referring to FIG. 8B, in the method for manufacturing the electronic device according to an embodiment, the step of forming the preliminary protective layer (S200) may include steps of: providing a mask on a second lower surface (S210), providing plasma on the mask (S220), and applying a resin composition (S230).

Meanwhile, FIGS. 9A to 9D are cross-sectional views schematically illustrating the step of forming the protective layer in the method for manufacturing the electronic device according to an embodiment of the invention. FIGS. 9A to 9C schematically illustrate the manufacturing steps on a cross section in which the third direction DR3 is in a reversed direction based on the above-described FIG. 7A, and FIG. 9D schematically illustrates the manufacturing step on a cross section corresponding to the above-described FIG. 7A.

FIGS. 9A and 9B schematically illustrate the step of forming the preliminary protective layer by applying a resin composition on a first lower surface (S200), FIG. 9C schematically illustrates the step of forming the first protective layer by curing the preliminary protective layer (S300), and FIG. 9D schematically illustrates the step of arranging the electronic module so as to overlap a second region (S400). Meanwhile, the step of forming the preliminary protective layer (S200) may include the step of: providing the mask on the second lower surface (S210), providing the plasma on the mask (S220), and applying the resin composition (S230). FIG. 9A schematically illustrates the step of providing the mask on the second lower surface (S210), and the step of providing the plasma on the mask and the first lower surface (S220), and FIG. 9B schematically illustrates the step of applying the resin composition (S230).

Referring to FIGS. 8B and 9A, a mask MK may be provided on a second lower surface LF2 of the display panel DP, and plasma PZ may be provided on the lower surface of the display panel DP after the mask MK is provided. Accordingly, the plasma PZ may be provided on a first lower surface LF1, and may not be provided on the second lower surface LF2. The plasma PZ may be oxygen (O₂) plasma, nitrogen (N₂) plasma, or argon (Ar) plasma, but an embodiment of the invention is not limited thereto. The step of providing the plasma PZ on the mask MK may include a process of irradiating the first lower surface LF1 with oxygen (O₂) plasma, nitrogen (N₂) plasma, or argon (Ar) plasma. The step of providing the plasma PZ on the mask MK may be substantially a step of performing a hydrophilic treatment on the first lower surface LF1. Accordingly, the contact angle between the first lower surface LF1 and water may be smaller than the contact angle between the second lower surface LF2 and water.

Referring to FIGS. 8B and 9B, a resin composition RS may include a curable resin. The resin composition RS may include at least one among an acylate-based resin, a urethane-based resin, a fluorine-based resin, an epoxy-based resin, a polyester-based resin, a polyamide-based resin, and a silicone-based resin, which have curability. The curable resin which is included in the resin composition RS and a preliminary protective layer PPR (see FIG. 9C) may be in a liquid form before being cured.

The resin composition RS may be applied onto the lower surface of the display panel DP. The resin composition RS may be applied through any one method among spin coating, slit coating, jet printing, metal mask printing, and screen printing. For example, the resin composition RS may be applied through a screen printing process, or a slit coating process.

The resin composition RS may be applied onto the first lower surface LF1. Since the plasma PZ (see FIG. 9A) described above is emitted only to the first lower surface LF1, with respect to the curable resin included in the resin composition RS, the contact angle between the first lower surface LF1 and the curable resin included in the resin composition RS may be smaller than the contact angle between the second lower surface LF2 and the curable resin. Accordingly, the resin composition RS may be applied onto the first lower surface LF1 so as to overlap a first region NSA, and may not be applied onto the second lower surface LF2 so as not to overlap a second region SA. In the method for manufacturing the electronic device according to an embodiment of the invention, the resin composition RS may be uniformly applied so as to correspond to the first region NSA, thereby resulting in improvement in the reliability of the electronic device thus manufactured. However, an embodiment of the invention is not limited thereto, and even though the resin composition RS is applied to at least a portion of the second lower surface LF2, the method for manufacturing the electronic device according to an embodiment of the invention may also include a process of removing the resin composition RS applied onto the second lower surface LF2.

The resin composition RS may be directly applied onto the first lower surface LF1. Accordingly, an additional adhesive layer between the display panel DP and a first protective layer PL1 (see FIG. 9D) which is formed thereafter is unnecessary, and thus the reliability of the manufactured electronic device may be improved.

Referring to FIGS. 8A and 9C, the method for manufacturing the electronic device according to an embodiment includes the step of forming the first protective layer by curing the preliminary protective layer (S300). The preliminary protective layer PPR may be formed of the applied resin composition RS (see FIG. 9B), and the first protective layer may be formed by curing the preliminary protective layer PPR. The step of curing the preliminary protective layer PPR may be a step of forming the first protective layer PL1 (see FIG. 9D) by providing light UV to the preliminary protective layer PPR. For example, the light UV may be ultraviolet rays having a central wavelength in a wavelength range of about 100 nm to about 400 nm. The preliminary protective layer PPR may include a curable resin, and be photocured upon receiving the light UV. However, an embodiment of the invention is not limited thereto, and the step of curing the preliminary protective layer PPR may also be a step of forming the first protective layer PL1 (see FIG. 9D) by providing heat on the preliminary protective layer PPR. The preliminary protective layer PPR may be thermally cured upon receiving heat.

Meanwhile, FIGS. 8A, 8B, and 9A to 9C illustrate the step of forming the first protective layer PL1 (see FIG. 9D) in detail, and the step of forming the first protective layer PL1 (see FIG. 9D) described above may also be similarly applied to a step of forming the second protective layer PL2 (see FIG. 7B). For example, the step of forming the second protective layer PL2 (see FIG. 7B) may include steps of: providing the mask MK on the third lower surface LF3 (see FIG. 7B), providing the plasma PZ on the mask MK, applying the preliminary protective layer PPR on the fourth lower surface LF4 (see FIG. 7B), and curing the applied preliminary protective layer PPR. Also, although not illustrated, the first protective layer PL1 and the second protective layer PL2 may be formed by the same material and through the same process at the same time. For example, the step of forming the first and second protective layers PL1 and PL2 (see FIG. 7B) may include steps of: providing the mask MK on the second lower surface LF2 and the third lower surface LF3 (see FIG. 7B), providing the plasma PZ on the mask MK, applying the preliminary protective layer PPR on the first lower surface LF1 and the fourth lower surface LF4 (see FIG. 7B), and curing the applied preliminary protective layer PPR.

Referring to FIGS. 8A and 9D, the method for manufacturing the electronic device according to an embodiment includes the step of arranging the electronic module EM (S400). The electronic module EM may be arranged so as to overlap the second region SA of the display panel DP. The hole HH of the first protective layer PL1 overlaps the second region SA, and thus the electronic module EM may operate without deterioration of optical properties even though the electronic module EM is arranged so as to overlap the second region SA.

In the case of the electronic device according to an embodiment of the invention, the characteristic of a region in which the protective layer PL is disposed differs from the characteristic of a region in which the protective layer PL is not disposed, in the lower surface of the display panel DP, and thus the reliability of the electronic device and of the manufacturing process of the electronic device may be improved. The first lower surface LF1 of the display panel DP according to an embodiment of the invention is defined in the first region NSA in which the protective layer PL is disposed, and the second lower surface LF2 of the display panel DP is defined in the second region SA in which the protective layer PL is not disposed and the electronic module EM is arranged. In the electronic device according to an embodiment of the invention, the first lower surface LF1 has a smaller contact angle with respect to water than the second lower surface LF2, and thus it is possible to improve the thickness uniformity of the protective layer PL and the shaping reliability. In the method for manufacturing the electronic device according to an embodiment of the invention, the protective layer PL may be formed through slit coating, which is direct coating, or screen printing, and thus the manufacturing efficiencies for the electronic device may be increased.

Meanwhile, in a method for manufacturing an electronic device of another embodiment, the step of forming the preliminary protective layer (S200) may not include the steps of: providing the mask on the second lower surface (S210) and providing the plasma on the mask (S220).

FIGS. 10A and 10B are cross-sectional views schematically illustrating some steps of forming a preliminary protective layer in a method for manufacturing an electronic device according to other embodiments of the invention. In another embodiment, the step of forming the preliminary protective layer (S200) may include steps of: providing plasma on a first lower surface and applying a resin composition. In still another embodiment, the step of forming the preliminary protective layer (S200) may include steps of: performing a hydrophobic treatment on a second lower surface and applying the resin composition. FIG. 10A is a view schematically illustrating the step of providing the plasma on the first lower surface, and FIG. 10B is a view schematically illustrating the step of performing the hydrophobic treatment on the second lower surface.

Referring to FIG. 10A, a plasma PZ may be provided on a first lower surface LF1. The plasma PZ may be provided on the first lower surface LF1 via an apparatus ME of emitting the plasma PZ. The apparatus ME of emitting the plasma PZ may emit the plasma PZ on the first lower surface LF1 overlapping a first region NSA, and may not emit the plasma PZ on a second lower surface LF2 overlapping a second region SA. Specifically, the apparatus ME of emitting the plasma PZ moves in one direction, and while moving, the apparatus ME of emitting the plasma PZ may emit the plasma PZ when overlapping the first region NSA, and does not emit the plasma PZ when not overlapping the second region SA. The step of providing the plasma PZ on the first lower surface LF1 may be substantially the step of performing the hydrophilic treatment on the first lower surface LF1. Accordingly, the contact angle between the first lower surface LF1 and water may be smaller than the contact angle between the second lower surface LF2 and water.

Referring to FIG. 10B, the hydrophobic treatment may be performed on the second lower surface LF2. The step of performing the hydrophobic treatment on the second lower surface LF2 may be performed through a water-repellent coating process. When performing the hydrophobic treatment on the second lower surface LF2 through the water-repellent coating process, a water-repellent coating layer AC may be provided on the second lower surface LF2. The water-repellent coating layer AC may be provided on the second lower surface LF2 overlapping the second region SA, and may not be provided on the first lower surface LF1 overlapping the first region NSA. The water-repellent coating layer AC may be directly disposed on the second lower surface LF2, and may not be in contact with the first lower surface LF1. The water-repellent coating layer AC may include a fluorine-based resin. For example, the water-repellent coating layer AC may include polytetrafluoroethylene (PTFE), perfluoroalkoxy alkane (PFA), or fluorinated ethylene propylene (FEP). Alternatively, the water-repellent coating layer AC may include self-assembled monolayers (SAMs). However, the material of the water-repellent coating layer AC is not limited thereto, and any material may be used without a limitation as long as capable of performing a function that the contact angle between the second lower surface LF2 and water is relatively greater than the contact angle between the first lower surface LF1 and water. According to an embodiment of the invention, in an electronic device,

a lower surface of a display panel overlapping a transmission region is made to differ in characteristics from a lower surface of the display panel overlapping the other region. Accordingly, when disposing a protective layer under the display panel, it is possible to easily make a shape of the protective layer, thereby improving the reliability of the electronic device.

Additionally, according to an embodiment of the invention, since when manufacturing an electronic device, a lower surface of a display panel overlapping a transmission region is made to differ in characteristics from a lower surface of the display panel overlapping the other region, manufacturing efficiency is increased during formation of a protective layer disposed under the display panel, thereby resulting in improvement in the reliability of the electronic device thus manufactured.

Although the embodiments of the invention have been described, it is understood that the invention should not be limited to these embodiments but various changes and modifications can be made by one ordinary skilled in the art within the spirit and scope of the invention as hereinafter claimed. Therefore, the technical scope of the invention is not limited to the contents described in the detailed description of the specification, but should be determined by the claims.

What is claimed is:

1. An electronic device comprising:
a display panel including a first region, and a second region adjacent to the first region;
a protective layer overlapping the first region and disposed under the display panel; and
an electronic module overlapping the second region and disposed below the display panel,
wherein a lower surface of the display panel includes a first lower surface overlapping the first region and a second lower surface overlapping the second region, and
a contact angle between the first lower surface and water is smaller than a contact angle between the second lower surface and water.

2. The electronic device of claim 1, wherein the protective layer comprises a curable resin, and
a contact angle between the first lower surface and a liquid form of the curable resin is smaller than a contact angle between the second lower surface and the liquid form of the curable resin.

3. The electronic device of claim 2, wherein the protective layer further comprises a heat dissipation material dispersed in the curable resin.

4. The electronic device of claim 1, further comprising a heat dissipation layer disposed below the protective layer.

5. The electronic device of claim 1, wherein the protective layer is directly disposed on the first lower surface.

6. The electronic device of claim 1, wherein in the protective layer, a hole is defined, and the hole overlaps the second region.

7. The electronic device of claim 6, wherein the protective layer extends in a certain direction away from the hole,
wherein the protective layer comprises
a first side surface which defines the hole and has a first inclination with respect to the lower surface of the display panel, and
a second side surface which has a second inclination with respect to the lower surface of the display panel and is opposed to the first side surface in the certain direction, and
wherein the first inclination being greater than the second inclination.

8. The electronic device of claim 1, wherein the display panel comprises:
a first non-bending region including the first region and the second region;
a second non-bending region facing the first non-bending region; and
a bending region defined between the first non-bending region and the second non-bending region and having a predetermined radius of curvature.

9. The electronic device of claim 8, further comprising a circuit board disposed so as to overlap the second non-bending region.

10. The electronic device of claim 8, wherein the lower surface of the display panel further comprises a third lower surface overlapping the bending region, and
a contact angle between the first lower surface and water is smaller than a contact angle between the third lower surface and water.

11. The electronic device of claim 1, further comprising a window disposed above the display panel.

12. The electronic device of claim 1, wherein the lower surface of the display panel is formed of polyimide.

13. The electronic device of claim 1, wherein the protective layer has a thickness of about 50 micrometers (μm) to about 300 μm.

14. An electronic device comprising:
a display panel including a non-bending region, and a bending region which is adjacent to the non-bending region and has a predetermined radius of curvature;
a circuit board overlapping the non-bending region and electrically connected to the display panel; and
a protective layer overlapping the non-bending region and disposed under the display panel,
wherein a lower surface of the display panel includes a first panel lower surface overlapping the non-bending region and a second panel lower surface overlapping the bending region, and
a contact angle between the first panel lower surface and water is smaller than a contact angle between the second panel lower surface and water.

15. A method for manufacturing an electronic device, the method comprising:
providing a display panel which includes a first region and a second region adjacent to the first region, and a lower surface of which includes a first lower surface overlapping the first region and a second lower surface overlapping the second region;
forming a preliminary protective layer by applying a resin composition onto the first lower surface;
forming a protective layer by curing the preliminary protective layer; and
arranging an electronic module so as to overlap the second region,
wherein a contact angle between the first lower surface and water is smaller than a contact angle between the second lower surface and water.

16. The method of claim 15, wherein in the forming of the preliminary protective layer, the applying of the resin composition is performed through a screen printing process or a slit coating process.

17. The method of claim 15, wherein the forming of the preliminary protective layer comprises, before the applying of the resin composition:
providing a mask on the second lower surface; and
providing plasma on the mask and the first lower surface.

18. The method of claim 15, wherein the forming of the preliminary protective layer comprises, before the applying of the resin composition, providing plasma on the first lower surface, not on the second lower surface.

19. The method of claim 15, wherein the forming of the preliminary protective layer comprises, before the applying of the resin composition, performing a hydrophobic treatment on the second lower surface.

20. The method of claim 19, wherein the performing of the hydrophobic treatment on the second lower surface is performed through a water-repellent coating process.
